(19) United States
(12) Patent Application Publication
(10) Pub. No.: US 2026/0006788 A1
(43) Pub. Date: Jan. 1, 2026

(54) MEMORY DEVICE AND MANUFACTURING METHOD OF THE MEMORY DEVICE

(71) Applicant: SK hynix Inc., Icheon-si Gyeonggi-do (KR)

(72) Inventors: Do Young KIM, Icheon-si Gyeonggi-do (KR); Jin Ha KIM, Icheon-si Gyeonggi-do (KR); Changhan Kim, Icheon-si Gyeonggi-do (KR)

(73) Assignee: SK hynix Inc., Icheon-si Gyeonggi-do (KR)

(21) Appl. No.: 19/033,971

(22) Filed: Jan. 22, 2025

(30) Foreign Application Priority Data
Jul. 1, 2024 (KR) 10-2024-0086224

(51) Int. Cl. H10B 43/27; H10B 43/35

(52) U.S. Cl. CPC H10B 43/27; H10B 43/35

(57) ABSTRACT

A memory device includes conductive patterns and first interlayer insulating layers stacked alternately with each other in a first direction, a dummy pattern separated from the conductive patterns in the first direction, a second interlayer insulating layer located between the conductive patterns and the dummy pattern, protruding patterns protruding in a second direction crossing the first direction from side surfaces of the first interlayer insulating layers and a side surface of the second interlayer insulating layer, and data storage patterns located between the protruding patterns.

### CROSS-REFERENCE TO RELATED APPLICATION

The present application claims priority under 35 U.S.C. § 119(a) to Korean patent application number 10-2024-0086224 filed on Jul. 1, 2024, in the Korean Intellectual Property Office, the entire contents of which application is incorporated herein by reference.

### BACKGROUND

### 1. Technical Field

The present disclosure relates to a memory device and a manufacturing method of the memory device, and more particularly, to a memory device including a memory block having a three-dimensional structure, and a method of manufacturing the memory device.

### 2. Related Art

Memory devices may include non-volatile memory devices that retain stored data even in the absence of power supply. Non-volatile memory devices may be divided into two-dimensionally structured memory devices or three-dimensionally structured memory devices, depending on arrangements of memory cells. Memory cells of a non-volatile memory device having a two-dimensional structure may be arranged in a single layer on a substrate. Memory cells of a non-volatile memory device having a three-dimensional structure may be stacked in a vertical direction to the substrate. Because an integration density of the non-volatile memory device having the three-dimensional structure is greater than that of the non-volatile memory device having the two-dimensional structure, electronic devices including three-dimensionally structured non-volatile memory devices have been increasing.

### SUMMARY

According to an embodiment, a memory device may include conductive patterns and first interlayer insulating layers stacked alternately with each other in a first direction, a dummy pattern separated from the conductive patterns in the first direction, a second interlayer insulating layer located between the conductive patterns and the dummy pattern, protruding patterns protruding in a second direction crossing the first direction from side surfaces of the first interlayer insulating layers and a side surface of the second interlayer insulating layer, and data storage patterns located between the protruding patterns.

According to an embodiment, a method of manufacturing a memory device may include forming a preliminary stack structure including sacrificial layers and first interlayer insulating layers stacked alternately with each other in a first direction, a dummy layer separated from the sacrificial layers in the first direction, and a second interlayer insulating layer located between the sacrificial layers and the dummy layer, forming an opening extending in the first direction in the preliminary stack structure, forming protruding patterns on side surfaces of the first interlayer insulating layers and a side surface of the second interlayer insulating layer in the opening, and forming data storage patterns located between the protruding patterns.

### BRIEF DESCRIPTION OF THE DRAWINGS

FIG. 1 is a diagram illustrating a memory device according to an embodiment of the present disclosure;

FIG. 2 is a circuit diagram illustrating a memory block according to an embodiment of the present disclosure;

FIG. 3 is a cross-sectional view illustrating the structure of a memory device according to an embodiment of the present disclosure;

FIGS. 4A, 4B, 4C, 4D, 4E, 4F, and 4G are diagrams illustrating a method of manufacturing a semiconductor device according to an embodiment of the present disclosure;

FIG. 5 is a cross-sectional view illustrating the structure of a memory device according to an embodiment of the present disclosure;

FIGS. 6A, 6B, 6C, 6D, 6E, 6F, and 6G are diagrams illustrating a method of manufacturing a memory device according to an embodiment of the present disclosure;

FIG. 7 is a diagram illustrating a memory card system to which a memory device according to an embodiment of the present disclosure is applied; and

FIG. 8 is a diagram illustrating a solid state drive (SSD) system to which a memory device according to various embodiments of the present disclosure is applied.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Hereinafter, various embodiments of the present disclosure will be described in detail with reference to the accompanying drawings in order for those skilled in the art to be able to implement the technical spirit of the present disclosure. It will be understood that although the terms “first,” “second,” “third,” etc. are used herein to describe various elements, these elements should not be limited by these terms. These terms are only used to distinguish one element from another element and are not intended to imply an order or number of elements. Thus, a first element in some embodiments could be termed a second element in other embodiments without departing from the teachings of the present disclosure. Spatially relative terms, such as “beneath,” “below,” “lower,” “above,” “upper,” “over,” “under,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly.

According to embodiments of the present disclosure, a memory device in which data storage patterns separated from each other in a vertical direction are stably formed, and a method of manufacturing the memory device are provided.

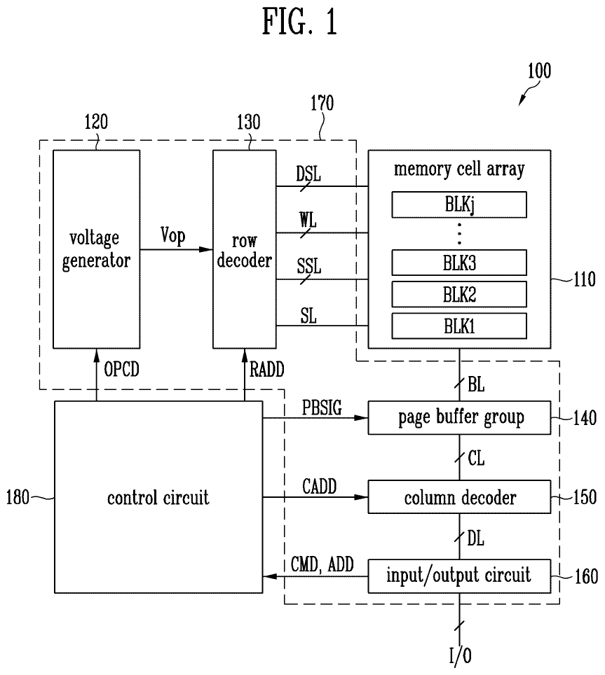

FIG. 1 is a diagram illustrating a memory device 100 according to an embodiment of the present disclosure.

Referring to FIG. 1, the memory device 100 may include a memory cell array 110, a peripheral circuit 170, and a control circuit 180.

The memory cell array 110 may include first to jth memory blocks BLK1 to BLKj. The first to jth memory blocks BLK1 to BLKj may have a three-dimensional structure. The three-dimensionally structured first to jth memory blocks BLK1 to BLKj may include memory cells which are stacked in a vertical direction to a substrate.

The memory cells may store one or more bits of data according to a program method. For example, a method of storing one bit in a single memory cell is referred to as a single-level cell method, and a method of storing two bits of data is referred to as a multi-level cell. A method of storing three bits of data in a single memory cell is referred to as a triple-level cell method. A method of storing four bits of data is referred to as a quad level cell method.

The peripheral circuit 170 may include a program operation for storing data in the memory cell array 110, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop applied to perform a program operation, a read operation, or an erase operation in response to an operation code OPCD. For example, the voltage generator 120 may generate program voltages, program voltages, turn-off voltages, turn-off voltages, a ground voltage, negative voltages, source voltages, verify voltages, read voltages, erase voltages, and precharge voltages in response to the operation code OPCD.

Program voltages may be applied to a selected word line among word lines WL during a program operation and may be used to increase threshold voltages of memory cells coupled to the selected word line. Pass voltages may be applied to unselected word lines among the word lines WL during a program or read and may be used to turn on memory cells coupled to the unselected word lines.

Turn-on voltages may be applied to drain select lines DSL or source select lines SSL and may be used to turn on drain select transistors or source select transistors. Turn-off voltages may be applied to the drain select lines DSL or the source select lines SSL and may be used to turn on the drain select transistors or the source select transistors.

A ground voltage may be 0 V. Negative voltages may be lower than 0 V. Source voltages may be applied to a source line SL and may be a negative voltage, a ground voltage, or a positive voltage. Verify voltages may be used for determining threshold voltages of selected memory cells during a program or erase operation and may be applied to the selected word line or all word lines coupled to the selected memory block.

Read voltages may be applied to the selected word line during a read operation and may be used to determine data stored in the memory cells. Erase voltages may be applied to the source line SL during an erase operation and may be used for lowering the threshold voltages of the memory cells. A precharge voltage may be a positive voltage for precharging a channel of unselected strings during a verify or read operation and may be applied to the source line SL.

The row decoder 130 may be coupled to the voltage generator 120 through global lines and to the first to jth memory blocks BLK1 to BLKj through the drain select lines DSL, the word lines WL, the source select lines SSL, and the source line SL. The row decoder 130 may be configured to apply the operating voltages Vop to the drain select lines DSL, the word lines WL, the source select lines SSL, and the source line SL which are coupled to the selected memory block depending on a row address RADD.

The page buffer group 140 may include page buffers (not shown) which are commonly coupled to the first to jth memory blocks BLK1 to BLKj. For example, each of the page buffers (not shown) may be coupled to the first to jth memory blocks BLK1 to BLKj through bit lines BL. The page buffers (not shown) may sense currents or voltages in the bit lines BL in response to page buffer control signals PBSIG.

The column decoder 150 may transfer data between the page buffer group 140 and the input/output circuit 160 in response to a column address CADD. For example, the column decoder 150 may be coupled to the page buffer group 140 through column lines CL and to the input/output circuit 160 through the column lines CL.

The input/output circuit 160 may receive or output a command CMD, an address ADD and data through input/output lines I/O. For example, the input/output circuit 160 may transfer the command CMD and the address ADD, which are received from an external device through the input/output lines I/O, to the control circuit 180, and may transfer the data, which is received from the external controller through the input/output lines I/O, to the column decoder 150. Alternatively, the input/output circuit 160 may output the data, which is transferred from the column decoder 150, to the external controller through the input/output lines I/O.

The control circuit 180 may output the operation code OPCD, the row address RADD, the page buffer control signals PBSIG, and the column address CADD in response to the command CMD and the address ADD. For example, when the command CMD which is input to the control circuit 180 corresponds to a program operation, the control circuit 180 may control the peripheral circuit 170 to perform a program operation of the selected memory block by the address ADD. When the control circuit 180 corresponds to a read operation, the control circuit 180 may control the peripheral circuit 170 to perform a read operation of the selected memory block by the address, and to output the read data. When the command CMD which is input to the control circuit 180 corresponds to an erase operation, the control circuit 180 may control the peripheral circuit 170 to perform the erase operation of the selected memory block.

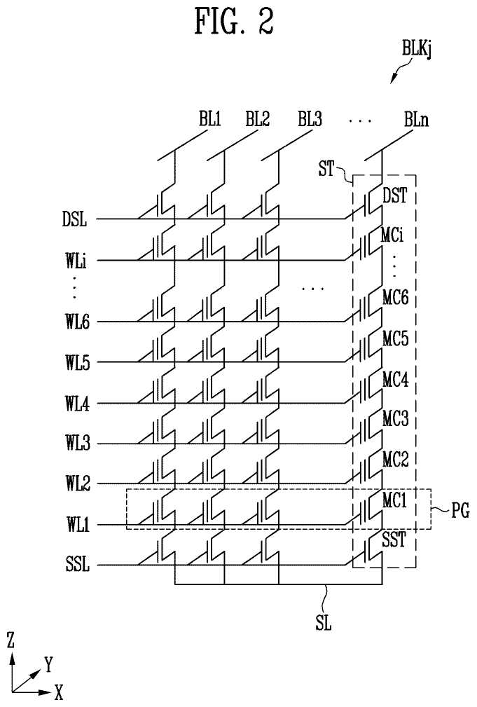

FIG. 2 is a circuit diagram illustrating a memory block according to an embodiment of the present disclosure.

The first to jth memory blocks bLK1 to BLKj as shown in FIG. 1 may have the same configuration. FIG. 2 shows the jth memory block BLKj as an example among the first to jth memory blocks bLK1 to BLKj.

Referring to FIG. 2, the jth memory block BLKj may include strings ST which couple first to nth bit lines BL1 to BLn and the source line SL. The first to nth bit lines BL1 to BLn may extend in a Y direction and be spaced apart from each other in an X direction. Thus, the strings ST which extend in a Z direction may be spaced apart from each other in the X and Y directions.

One of the strings ST coupled to the nth bit line BLn is described as an example. The string ST may include a source select transistor SST, first to ith memory cells MC1 to MCi, and a drain select transistor DST. FIG. 2 which shows the jth memory block BLKj schematically illustrates the connecting configuration of the memory block. Thus, the number of source select transistors SST, the number of first to ith memory cells MC1 to MCi, and the number of drain select transistors DST may vary depending on memory devices. For example, the string ST may include two or more source select transistors SST or two or more drain select transistors DST.

Gates of the source select transistors SST included in different cell strings ST may be coupled to the source select lines SSL. Gates of the first to ith memory cells MC1 to MCi may be coupled to first to ith word lines WL1 to WLi. Gates of the drain select transistors DST may be coupled to the drain select lines DSL.

Memory cells included in the same layer among the first to ith memory cells MC1 to MCi may be coupled to the same word line. For example, the first memory cells MC1 included in different strings ST may be commonly coupled to the first word line WL1 and the ith word line WLi, and the ith memory cells MCi included in different strings ST may be commonly coupled to the ith word line WLi. A group of memory cells which are included in different strings ST and are coupled to the same word line may constitute a page PG. Program and read operations may be in units of pages PG, and an erase operation may be performed in units of memory blocks.

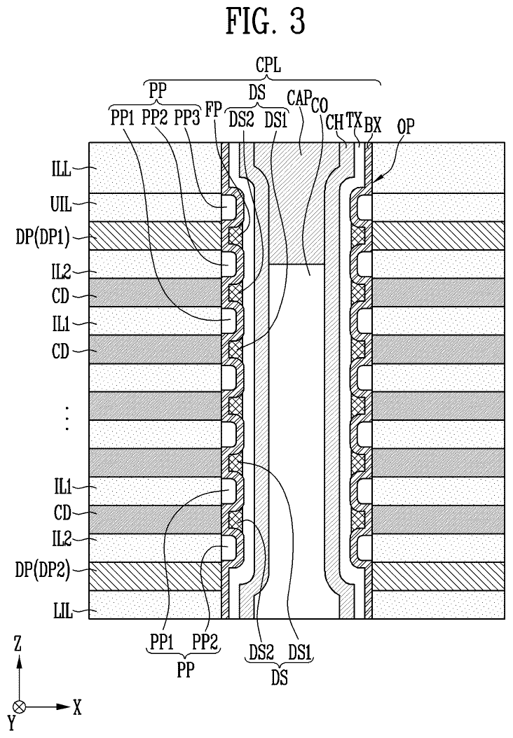

FIG. 3 is a cross-sectional view illustrating the structure of a memory device according to an embodiment of the present disclosure.

A cell plug CPL shown in FIG. 3 may correspond to any one of the strings ST included in any one memory block among the first to jth memory blocks BLK1 to BLKj shown in FIG. 1. For example, the source select transistor SST, the first to ith memory cells MC1 to MCi, and the drain select transistor DST may be formed at intersections between the cell plug CPL and conductive patterns CD.

Referring to FIG. 3, the memory device may include the conductive patterns CD and first interlayer insulating layers IL1 which are stacked alternately with each other in a Z axis (i.e., first direction). The conductive patterns CD may be insulated from each other by the first interlayer insulating layer IL1. Each of the first interlayer insulating layers IL1 may be located between the conductive patterns CD. For example, the conductive patterns CD may be located over and under each of the first interlayer insulating layers IL1. The conductive patterns CD may include the drain select lines DSL, the word lines WL, and the source select lines SSL which are described above with reference to FIGS. 1 and 2. However, the number of layers on which the conductive patterns CD are stacked as shown in FIG. 3 is a mere example, and is not limited to FIG. 3.

The memory device may include dummy patterns DP which are separated from the conductive patterns CD. The dummy patterns DP may be separated from the conductive patterns CD in the Z direction. For example, a first dummy pattern DP1 may be disposed over the conductive patterns CD. In addition, a second dummy pattern DP2 may be located under the conductive patterns CD. However, the dummy patterns DP of FIG. 3 correspond to a mere example. The memory device may include any one of the first dummy pattern DP1 and the second dummy pattern DP2.

The memory device may include second interlayer insulating layers IL2 which are located between the conductive patterns CD and the dummy pattern DP. Each of the second interlayer insulating layers IL2 may contact the conductive pattern CD and the dummy pattern DP. For example, the second interlayer insulating layer IL2 may be located between the first dummy pattern DP1 and the uppermost conductive pattern CD among the conductive patterns CD. The first dummy pattern DP1 may be located adjacent to the conductive pattern CD with the second interlayer insulating layer IL2 interposed therebetween. In addition, the second interlayer insulating layer IL2 may be located between the second dummy pattern DP2 and the lowermost conductive pattern CD among the conductive patterns CD. The second dummy pattern DP2 may be located adjacent to the conductive pattern CD with the second interlayer insulating layer IL2 interposed therebetween.

The memory device may further include an upper insulating layer UIL over the first dummy pattern DP1. The memory device may further include a lower insulating layer LIL under the second dummy pattern DP2. The memory device may further include an insulating layer ILL over the upper insulating layer UIL. For example, the insulating layer ILL may correspond to a hard mask. In another example, the insulating layer ILL may correspond to a layer which replaces the hard mask.

The conductive patterns CD may include a conductive material. For example, the conductive patterns CD may include at least one of tungsten (W), cobalt (Co), nickel (Ni), molybdenum (Mo), silicon (Si), and polysilicon (Poly-Si).

The first interlayer insulating layers IL1 and the second interlayer insulating layers IL2 may include the same material. For example, each of the first interlayer insulating layers IL1 and the second interlayer insulating layers IL2 may include an oxide layer. Each of the first interlayer insulating layers IL1 and the second interlayer insulating layers IL2 may include a silicon oxide layer or an oxide material corresponding thereto. The upper insulating layer UIL and the lower insulating layer LIL may include the same materials as the first and second interlayer insulating layer IL1 and IL2. Each of the upper insulating layer UIL and the lower insulating layer LIL may include a silicon oxide layer or an oxide material corresponding thereto. The insulating layer ILL may include an oxide layer or a nitride layer.

The dummy patterns DP may include an insulating material. The dummy patterns DP may include a different insulating material from the first and second interlayer insulating layers IL1 and IL2. The dummy patterns DP may include a nitride. For example, the dummy patterns DP may include silicon carbon nitride (SiCN).

The memory device may include the cell plug CPL. The cell plug CPL may extend in the Z direction. The cell plug CPL may pass through the conductive patterns CD, the first interlayer insulating layers IL1, the dummy patterns DP, and the second interlayer insulating layers IL2. The cell plug CPL may pass through the upper insulating layer UIL and the lower insulating layer LIL. For example, the memory device may include an opening OP which passes through the conductive patterns CD, the first interlayer insulating layers IL1, the dummy patterns DP, and the second interlayer insulating layers IL2, and the cell plug CPL may be located in the opening OP.

The cell plug CPL may include protruding patterns PP. The protruding patterns PP may extend from side surfaces of the first and second interlayer insulating layers IL1 and IL2 in a horizontal direction (i.e., X direction). For example, the protruding patterns PP may protrude toward the center of the opening OP from the side surfaces of the first and second interlayer insulating layers IL1 and IL2 which are exposed through the opening OP. Each of the protruding patterns PP may have a ring shape. The protruding patterns PP may be spaced apart from each other in the Z direction. An inner surface of each of the protruding patterns PP may have a convex surface toward the center of the opening OP.

First protruding patterns PP1 may be disposed on side surfaces of the first interlayer insulating layers IL1. Second protruding patterns PP2 may be disposed on side surfaces of the second interlayer insulating layers IL2. A third protruding pattern PP3 may be disposed on a side surface of the upper insulating layer UIL.

The protruding patterns PP may include an insulating material. For example, the protruding patterns PP may include an oxide layer. The protruding patterns PP may include a silicon oxide layer or an oxide material corresponding thereto.

The cell plug CPL may further include a blocking insulating layer BX which extends on surfaces of the protruding patterns PP. The blocking insulating layer BX may be formed on the surfaces of the protruding patterns PP and surfaces of the conductive patterns CD which are exposed through the opening OP. The blocking insulating layer BX may be conformally formed on the surfaces of the protruding patterns PP and the surfaces of the conductive patterns CD which are exposed through the opening OP. The protruding patterns PP may extend from a side surface of the opening OP, so that the blocking insulating layer BX may include an uneven structure. The blocking insulating layer BX may include a convex portion and a concave portion toward the center of the opening OP.

The blocking insulating layer BX may include an insulating material. For example, the blocking insulating layer BX may include an oxide layer. The blocking insulating layer BX may include a silicon oxide layer, a silicon oxynitride layer, or an oxide material corresponding thereto.

The cell plug CPL may include data storage patterns DS which are located between the protruding patterns PP. Each of the data storage patterns DS may be located between the protruding patterns PP spaced apart from each other in the Z direction. The data storage patterns DS may be located at the same levels as the conductive patterns CD. Each of the data storage patterns DS may be located in a horizontal direction with respect to each of the conductive patterns CD. Each of the data storage patterns DS may be located by each of the conductive patterns CD.

The data storage patterns DS may be formed in concave portions of the blocking insulating layer BX. The blocking insulating layer BX may extend between the protruding patterns PP and the data storage patterns DS. For example, the blocking insulating layer BX and the data storage patterns DS may be located between the protruding patterns PP which are continuously arranged in the Z direction. The protruding patterns PP and the data storage patterns DS may be separated from each other by the blocking insulating layer BX.

The data storage patterns DS may be separated from each other in the Z direction by the protruding patterns PP. The data storage patterns DS which are consecutively arranged in the Z direction may be separated by the blocking insulating layer BX and the protruding pattern PP. Because the data storage patterns DS formed on different layers are not coupled to each other and are separated from each other, negative charges trapped in the data storage patterns DS during a program operation might not move to other data storage patterns DS which are located adjacent in the vertical direction. In an embodiment, retention characteristics of the memory device may be improved by the data storage patterns DS separated from each other in the Z direction, so that the reliability of the memory device may be improved.

First data storage patterns DS1 may be located between the first protruding patterns PP1. For example, the first protruding patterns PP1 may be located over and under each of the first data storage patterns DS1. Second data storage patterns DS2 may be located between any one of the first protruding patterns PP1 and any one of the second protruding patterns PP2. For example, the first protruding pattern PP1 and the second protruding pattern PP2 may be located over and under each of the second data storage patterns DS2. That is, each of the second data storage patterns DS2 may be located at the same level as the uppermost conductive pattern CD and the lowermost conductive pattern CD among the conductive patterns CD.

The data storage patterns DS may include a nitride layer. For example, the data storage patterns DS may include a silicon nitride layer.

Referring to FIG. 3, the protruding patterns PP formed in the opening OP may have the same size and shape in the Z direction. For example, the size and shape of the second protruding patterns PP2 may correspond to that of the first protruding patterns PP1. In addition, the data storage patterns DS formed in the opening OP may have the same size and shape in the Z direction. For example, the size and shape of the second data storage patterns DS2 may correspond to that of the first data storage patterns DS1. That is, the structure of the cell plug CPL between the dummy patterns DP may include a regular pattern.

According to an embodiment of the present disclosure, because the memory device includes the dummy pattern DP which is spaced apart from the conductive patterns CD, the second protruding pattern PP2 formed on the side surface of the second interlayer insulating layer IL2 may have the same size and shape as the first protruding patterns PP1. Therefore, the second data storage pattern DS2 formed between the first protruding pattern PP1 and the second protruding pattern PP2 may have the same size and shape as the first data storage patterns DS1. Conventionally, it was difficult to stably form the data storage patterns on the side portions of the uppermost or lowermost conductive patterns CD. However, according to an embodiment of the present disclosure, the data storage patterns DS may be stably formed on the side portions of the uppermost or lowermost conductive patterns CD. In the present disclosure, the word ‘same’ as in the same size and shape means cases where both parties are equal to each other, where both are slightly different but are within an error range, and where they are substantially uniform.

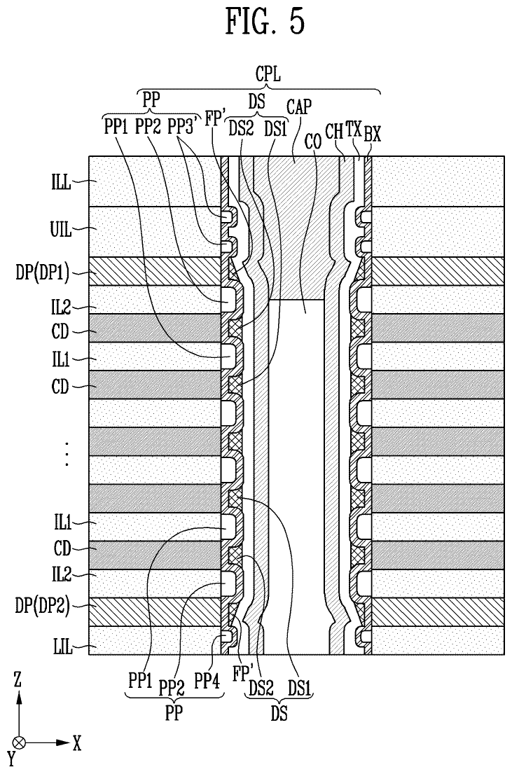

Referring to FIG. 3, a filling pattern FP may be located between the second protruding pattern PP2 and the third protruding pattern PP3. The filling pattern FP may be formed at the same level as the dummy pattern DP. The filling pattern FP may be surrounded by the dummy pattern DP. The filling pattern FP may include the same material as the data storage patterns DS. As shown in FIG. 3, the filling patterns FP may have the same shape and size as the data storage patterns DS. However, the present disclosure is not limited thereto. For example, the filling pattern FP may have a smaller size than the data storage patterns DS. This will be described below with reference to FIG. 5.

Referring to FIG. 3 again, the cell plug CPL may include a tunneling layer TX which contacts the data storage patterns DS and the blocking insulating layer BX. The tunneling layer TX may contact the data storage patterns DS at levels corresponding to the conductive patterns DS. In addition, the tunneling layer TX may contact the blocking insulating layer BX at levels corresponding to the first and second interlayer insulating layers IL1 and IL2. In addition, the tunneling layer TX may contact an inner surface of the filling pattern FP. The tunneling layer TX may include an insulating material. For example, the tunneling layer TX may include an oxide layer. The tunneling layer TX may include a silicon oxide layer or an oxide material corresponding thereto.

The cell plug CPL may include a channel layer CH which contacts an inner surface of the tunneling layer TX. For example, as illustrated in an embodiment in FIG. 3, the cell plug CPL may include a channel layer CH which contacts an inner surface of the tunneling layer TX. The channel layer CH may have a cylindrical shape between the dummy patterns DP. The channel layer CH may include an undoped silicon layer or a doped silicon layer.

The cell plug CPL may include a core pillar CO which fills the inside of the channel layer CH. The core pillar CO may be surrounded by the channel layer CH. The core pillar CO may have a cylindrical shape in an area surrounded by the channel layer CH between the dummy patterns DP. The core pillar CO may include an insulating layer or a conductive layer.

The cell plug CPL may include a capping layer CAP which is formed on the core pillar CO. The capping layer CAP may contact the channel layer CH on the core pillar CO. The capping layer CAP may include an undoped silicon layer or a doped silicon layer.

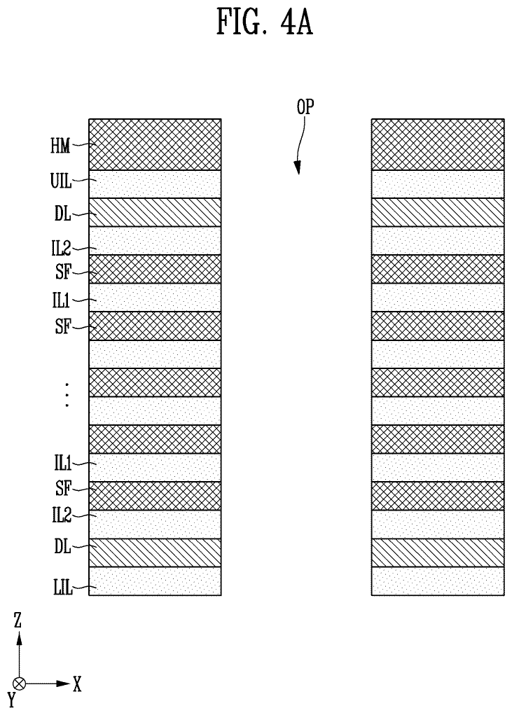

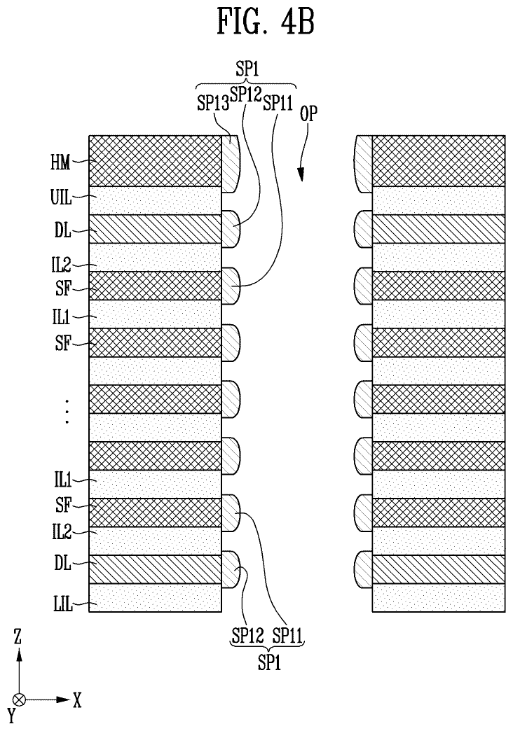

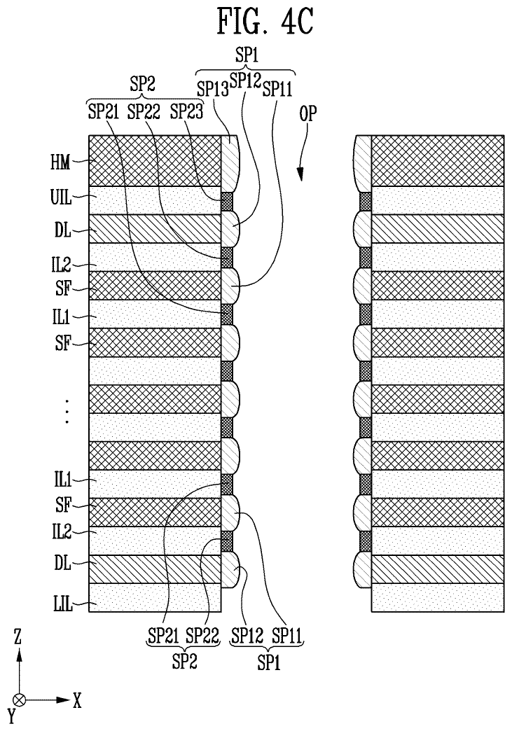

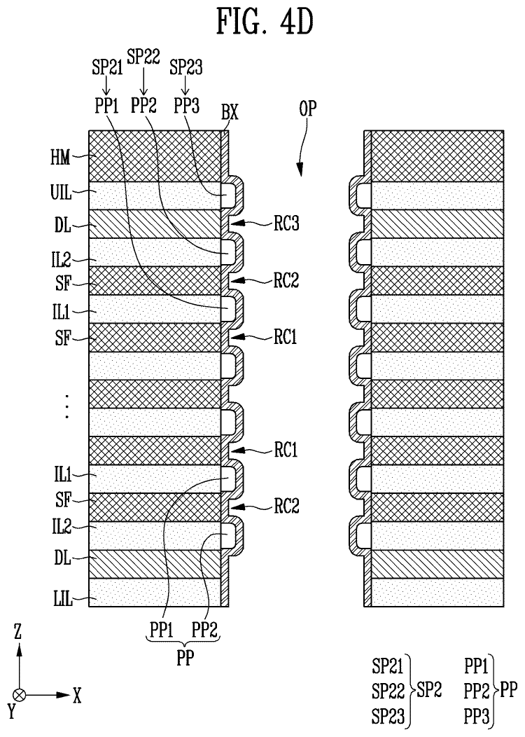

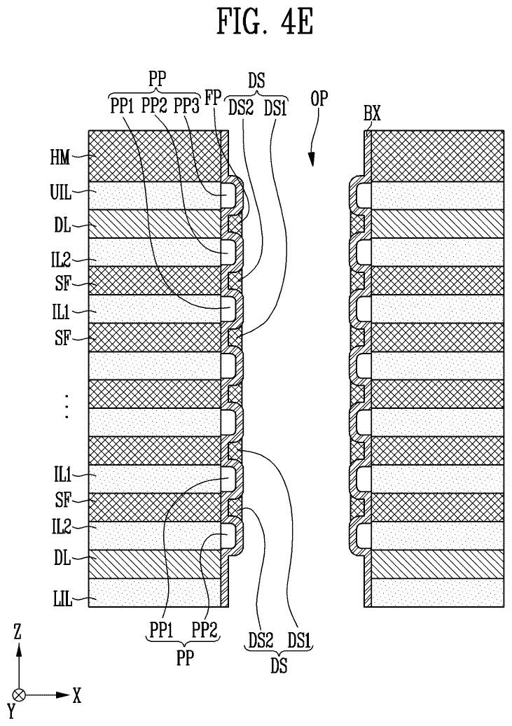

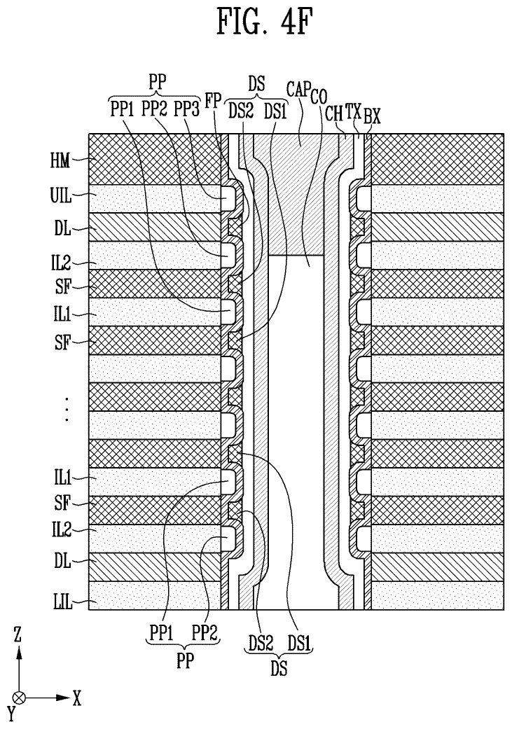

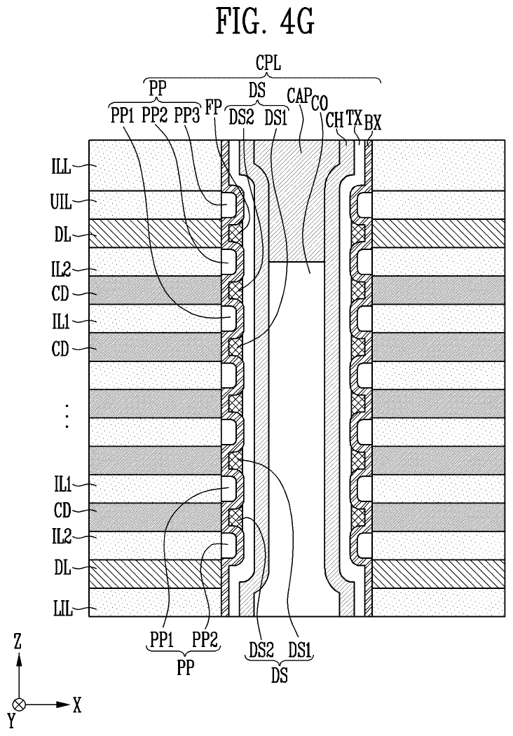

FIGS. 4A to 4G are diagrams illustrating a method of manufacturing a memory device according to an embodiment of the present disclosure.

Referring to FIG. 4A, the lower insulating layer LIL, a dummy layer DL, and the second interlayer insulating layer IL2 may be sequentially stacked in a Z direction. Subsequently, sacrificial layers SF and the first interlayer insulating layers IL1 may be alternately stacked in the Z direction. Subsequently, the second interlayer insulating layer IL2, the dummy layer DL, the upper insulating layer UIL, and a hard mask HM may be sequentially stacked in the Z direction. The dummy layer DL may be separated from the sacrificial layers SF in the Z direction. Each of the second interlayer insulating layers IL2 may be located between the sacrificial layer SF and the dummy layer DL. In the present disclosure, a stacked structure which includes at least the sacrificial layers SF, the dummy layers DL, and the first and second interlayer insulating layers IL1 and IL2 may be referred to as a preliminary stack structure.

The length of the sacrificial layers SF in the Z direction may be the same as that of the dummy layers DL in the Z direction. The length of the hard mask HM in the Z direction may be greater than the length of the sacrificial layers SF or the dummy layers DL in the Z direction. The hard mask HM may have a greater thickness than the sacrificial layers SF and the dummy layers DL.

The first and second interlayer insulating layers IL1 and IL2 may include an insulating material. For example, the first and second interlayer insulating layers IL1 and IL2 may include an oxide layer. The first and second interlayer insulating layers IL1 and IL2 may include a silicon oxide layer or an oxide material corresponding thereto. The sacrificial layers SF may include a material which is selectively removed during subsequent processes. The sacrificial layers SF may include a material having a different etch selectivity from the first and second interlayer insulating layers IL1 and IL2. The sacrificial layers SF may include a nitride. For example, the sacrificial layers SF may include a silicon nitride layer. The upper interlayer insulating layer UIL and the lower interlayer insulating layers LIL may include an oxide layer. Each of the upper insulating layer UIL and the lower insulating layer LIL may include a silicon oxide layer or an oxide material corresponding thereto. The hard mask HM may have the same material as the sacrificial layers SF.

The dummy layers DL may include an insulating material. The dummy layers DL may include a different insulating material from the first and second interlayer insulating layers IL1 and IL2. The dummy layers DL may include a different insulating material from the sacrificial layers SF. The dummy layers DL may include a nitride material. For example, the dummy layers DL may include silicon carbon nitride (SiCN).

Subsequently, the opening OP which extends in the Z direction may be formed in the preliminary stack structure. The opening OP may pass through the sacrificial layers SF, the dummy layers DL, and the first and second interlayer insulating layers IL1 and IL2 in the Z direction. In addition, the opening OP may pass through the upper insulating layer UIL, the lower insulating layer LIL, and the hard mask HM in the Z direction. The opening OP may have a shape of a hole which extends in the Z direction. Side surfaces of the sacrificial layers SF, the dummy layers DL, and the first and second interlayer insulating layers IL1 and IL2 may be exposed through the side surface of the opening OP.

Referring to FIG. 4B, first sacrificial patterns SP1 may be selectively formed on the sacrificial layers SF, the dummy layers DL, and the first and second interlayer insulating layers IL1 and IL2 exposed through the opening OP. The first sacrificial patterns SP1 may be selectively deposited on the side surfaces of the sacrificial layers SF and the side surfaces of the dummy layers DL. For example, the first sacrificial patterns SP1 may grow from surfaces of the sacrificial layers SF, the dummy layers DL, and the hard mask HM.

The first sacrificial patterns SP1 may include a material which is selectively deposited on a nitride. The dummy layers DL may include a different material from the sacrificial layers SF. However, the dummy layers DL may include a material which is also deposited on the dummy layers DL as well as the sacrificial layers SF. For example, the first sacrificial patterns SP1 may include a material which is selectively deposited on the material included in the dummy layers DL and the sacrificial layers SF. For example, the first sacrificial pattern SP1 may include silicon oxycarbide (SiOC).

The first sacrificial patterns SP1 may have a greater thickness than the sacrificial layers SF, the dummy layers DL, and the hard mask HM. The thickness of the consecutive first sacrificial patterns SP1 in the Z direction may be controlled so that the first sacrificial patterns SP1 might not contact each other. Therefore, the first interlayer insulating layers IL1, the second interlayer insulating layers IL2, and the upper insulating layer UIL may be exposed between the consecutive first sacrificial patterns SP1 in the Z direction.

The first sacrificial patterns SP1 may include (1-1)th sacrificial patterns SP11 formed on side surfaces of the sacrificial layers SF, (1-2)th sacrificial patterns SP12 formed on side surfaces of the dummy layers DL, and (1-3)th sacrificial patterns SP13 formed on a side surface of the hard mask HM.

According to an embodiment of the present disclosure, the first sacrificial patterns SP1 may be formed on the side surfaces of the dummy layers DL as well as the side surfaces of the sacrificial layers SF. Therefore, the first sacrificial patterns SP1 may be arranged at regular intervals. For example, in the conventional memory device which does not include the dummy layers DL, the distance between the (1-1)th sacrificial pattern SP11 and the (1-3)th sacrificial pattern SP13 may be greater than the distance between the (1-1)th sacrificial patterns SP11. However, in the memory device according to an embodiment of the present disclosure, the (1-2)th sacrificial patterns SP12 may be further formed on the side surfaces of the dummy layers DL. Thus, the distance between the (1-1)th sacrificial patterns SP11, the distance between the (1-1)th sacrificial pattern SP11 and the (1-2)th sacrificial pattern SP12, and the distance between the (1-2)th sacrificial pattern SP12 and the (1-3)th sacrificial pattern SP13 may be similar to each other.

Referring to FIG. 4C, second sacrificial patterns SP2 may be formed between the first sacrificial patterns SP1. Referring to FIG. 4C, the second sacrificial patterns SP2 may be separated from each other in the Z direction by the first sacrificial patterns SP1. The second sacrificial patterns SP2 may be formed on side surfaces of the first and second interlayer insulating layers IL1 and IL2 and the upper insulating layer UIL. The second sacrificial patterns SP2 may include silicon.

For example, a sacrificial material may be formed on an inner surface of the opening OP to completely fill between the first sacrificial patterns SP1. For example, the sacrificial material may cover the first sacrificial patterns SP1 and the side surfaces of the first and second interlayer insulating layers IL1 and IL2 and the upper and lower insulating layers UIL and LIL exposed through the side surface of the opening OP. Subsequently, the sacrificial material may be partially removed to form the second sacrificial patterns SP2. For example, a portion of the sacrificial material which is formed on the side surfaces of the first sacrificial patterns SP1 may be etched.

The second sacrificial patterns SP2 may include (2-1)th sacrificial patterns SP21 disposed between the (1-1)th sacrificial patterns SP11, (2-2)th sacrificial patterns SP22 disposed between the (1-1)th sacrificial pattern SP11 and the (1-2)th sacrificial pattern SP12, and a (2-3)th sacrificial pattern SP23 disposed between the (1-2)th sacrificial pattern SP12 and the (1-3)th sacrificial pattern SP13.

According to an embodiment of the present disclosure, the second sacrificial patterns SP2 may have the same size and shape. For example, the sacrificial patterns SP may have the same thickness in a horizontal direction. For example, in the conventional memory device which does not include the dummy layers DL, the distance between the (1-1)th sacrificial pattern SP11 and the (1-3)th sacrificial pattern SP13 was greater than the distance between the (1-1)th sacrificial patterns SP11. As a result, most of the sacrificial material between the (1-1)th sacrificial pattern SP11 and the (1-3)th sacrificial pattern SP13 was etched. However, according to an embodiment of the present disclosure, the first sacrificial patterns SP1 may be arranged at regular intervals by the (1-2)th sacrificial pattern SP12 on the dummy layers DL, the (2-2)th sacrificial patterns SP22 may have a similar shape and size to the (2-1)th sacrificial patterns SP21.

Referring to FIG. 4D, the first sacrificial patterns SP1 may be removed. An etch process may be performed to remove the first sacrificial patterns SP1. As the etch process, a dry or wet etch process may be performed. As the dry etch process, isotropic etching may be performed. During the dry etch process, a source gas which has higher etch selectivity with respect to the first sacrificial patterns SP1 than the second sacrificial patterns SP2 may be used. During the wet etch process, an etchant which has higher etch selectivity with respect to the first sacrificial patterns SP1 than the second sacrificial patterns SP2 may be used.

Subsequently, the second sacrificial patterns SP2 may be oxidized to form the protruding patterns PP. Because the second sacrificial patterns SP2 are oxidized to form the protruding patterns PP, the protruding patterns PP may have a greater volume than the second sacrificial patterns SP2. The protruding patterns PP may correspond to a silicon oxide layer because the second sacrificial patterns SP2 include silicon or a material including silicon.

The (2-1)th sacrificial patterns SP21 may change into the first protruding patterns PP1. The first protruding patterns PP1 may be disposed on the side surfaces of the first interlayer insulating layers IL1. The (2-2)th sacrificial patterns SP22 may change into the second protruding patterns PP2. The second protruding patterns PP2 may be disposed on the side surfaces of the second interlayer insulating layers IL2. The (2-3)th sacrificial patterns SP23 may change into the third protruding patterns PP3. The third protruding patterns PP3 may be disposed on a side surface of the upper insulating layer UIL.

According to an embodiment of the present disclosure, because the second sacrificial patterns SP2 of FIG. 4C have the same size and shape, the protruding patterns PP may also have the same size and shape. In addition, because the first sacrificial patterns SP1 of FIG. 4B have the same size and shape, the protruding patterns PP may be arranged at regular intervals.

Subsequently, the blocking insulating layer BX may extend on surfaces of the protruding patterns PP. The blocking insulating layer BX may be formed on the surfaces of the protruding patterns PP, the sacrificial layers SF, the dummy layers DL, and the hard mask HM which are formed on the side surface of the opening OP. The blocking insulating layer BX may include an oxide layer.

Because the protruding patterns PP protrude from the first and second interlayer insulating layers IL1 and IL2, the blocking insulating layer BX may have irregularities on the surfaces of the protruding patterns PP and the first and second interlayer insulating layers IL1 and IL2. In other words, the blocking insulating layer BX may include recesses (RC1, RC2, and RC3) between consecutive protruding patterns PP in the Z direction. For example, the blocking insulating layer BX may include first recesses RC1 located between the first protruding patterns PP1, second recesses RC2 located between the first protruding pattern PP1 and the second protruding pattern PP2, and a third recess RC3 located between the second protruding pattern PP2 and the third protruding pattern PP3.

According to an embodiment of the present disclosure, because the protruding patterns PP have a uniform size and shape and are arranged at regular intervals, the first, second, and third recesses RC1, RC2, and RC3 may have a uniform size and shape. For example, the second recesses RC2 may have the same length and depth as the first recesses RC1.

Referring to FIG. 4E, the storage patterns DS may be formed between the protruding patterns PP. The first and second recesses RC1 and RC2 included in the blocking insulating layer BX may be filled with the data storage patterns DS. In addition, the third recess RC3 of the blocking insulating layer BX may be filled with the filling pattern FP. For example, a data storage material may be formed to fill the first, second, and third recesses RC1, RC2, and RC3 of the blocking insulating layer BX. The data storage material may include a nitride layer and cover the entire surface of the blocking insulating layer BX. Subsequently, the data storage material may be removed from the lower part of the opening OP and the side surface of the blocking insulating layer BX. A dry etch process may be performed to remove a portion of the data storage material. For example, anisotropic dry etching may be performed such that the data storage material may remain in the first, second, and third recesses RC1, RC2, and RC3 of the blocking insulating layer BX. In the anisotropic dry etching, a source gas having higher etch selectivity with respect to the data storage material than the blocking insulating layer BX may be used. The data storage material which remains in the first, second, and third recesses RC1, RC2, and RC3 of the blocking insulating layer BX may be the data storage patterns DS or the filling pattern FP.

The data storage patterns DS may include the first data storage patterns DS1 located between the first protruding patterns PP1. The first data storage patterns DS1 may fill the first recesses RC1 shown in FIG. 4D. The data storage patterns DS may include the second data storage patterns DS2 located between any one of the first protruding patterns PP1 and any one of the second protruding patterns PP2. The second data storage patterns DS2 may fill the second recesses RC2 shown in FIG. 4D.

According to an embodiment the present disclosure, the data storage patterns DS may have a uniform size and shape. Because the protruding patterns PP are arranged at regular intervals and the first and second recesses RC1 and RC2 of the blocking insulating layer BX have a uniform size and shape, the second data storage patterns DS2 may have the same and size as the first data storage patterns DS1. For example, in the conventional memory device which does not include the dummy layers DL, data storage patterns formed on the side portion of the uppermost and lowermost sacrificial layers SF may have a smaller size than the remaining data storage patterns. However, according to an embodiment the present disclosure, the second data storage patterns DS2 formed on the side portions of the uppermost and lowermost sacrificial layers SF may have the same size and shape as the first data storage patterns DS1. According to an embodiment the present disclosure, the data storage patterns DS may be stably formed by adding the dummy layers DL to the upper and lower parts of the stacked structure.

Referring to FIG. 4F, the tunneling layer TX, the channel layer CH, the core pillar CO, and the capping layer CAP may be sequentially formed in the opening OP. The tunneling layer TX may contact the data storage patterns DS and the blocking insulating layer BX in the opening OP. The tunneling layer TX may be conformally formed on the side surfaces of the data storage patterns DS, the blocking insulating layer BX, and the filling pattern FP. The channel layer CH may contact an inner surface of the tunneling layer TX. The channel layer CH may be conformally formed on the side surface of the tunneling layer TX. The core pillar CO may contact an inner surface of the channel layer CH and fill the opening OP. The capping layer CAP may contact the channel layer CH on the core pillar CO. However, the specific configurations of the tunneling layer TX, the core pillar CO, and the capping layer CAP are not limited to those shown in FIG. 4F. The tunneling layer TX may include an oxide layer. The channel layer CH and the capping layer CAP may include a doped silicon layer or an undoped silicon layer. The core pillar CO may include an insulating layer or a conductive layer.

Referring to FIG. 4G, the sacrificial layers SF may be replaced by the conductive patterns CD. For example, an etch process may be performed to remove the sacrificial layers SF. Because the sacrificial layers SF are formed between the first and second interlayer insulating layers IL1 and IL2, isotropic etching or wet etching may be performed as the etch process. When the sacrificial layers SF are removed, empty spaces may be defined between the first and second interlayer insulating layers IL1 and IL2. The conductive layer CD may be formed in the spaces. The conductive patterns CD may include at least one of tungsten (W), cobalt (Co), molybdenum (Mo), silicon (Si), and polysilicon (Poly-Si). However, other various conductive patterns may be used to form the conductive patterns CD.

According to an embodiment the present disclosure, the dummy layers DL might not be replaced by the conductive layer CD. Because the dummy layers DL include a different material from that of the sacrificial layers SF, the dummy layers DL might not be removed when the sacrificial layers SF are removed. The dummy layers DL may include a material having resistance with respect to phosphoric acid. For example, the dummy layers DL may include a nitride which includes SiCN. Therefore, the dummy layers DL might not be removed by phosphoric acid when the sacrificial layers SF are removed by the phosphoric acid. The dummy layers DL may remain as the dummy layers DL of FIG. 3 in the final structure. Because the dummy layers DL include an insulating material, the dummy layers DL might not be involved in operations of the memory device. That is, according to an embodiment the present disclosure, the data storage patterns DS having repetitive patterns may be formed using the dummy layers DL during the manufacturing processes of the memory device, and the dummy layers DL may remain as the dummy patterns DP after the manufacturing processes of the memory device are completed, and might not interrupt operations of the memory device.

In addition, the hard mask HM may be replaced by the insulating layer ILL. For example, the hard mask HM may be etched and the insulating layer ILL may be formed in a space from which the hard mask HM is removed. The insulating layer ILL may include an oxide layer. In another example, the hard mask HM might not be removed and may remain as the insulating layer ILL.

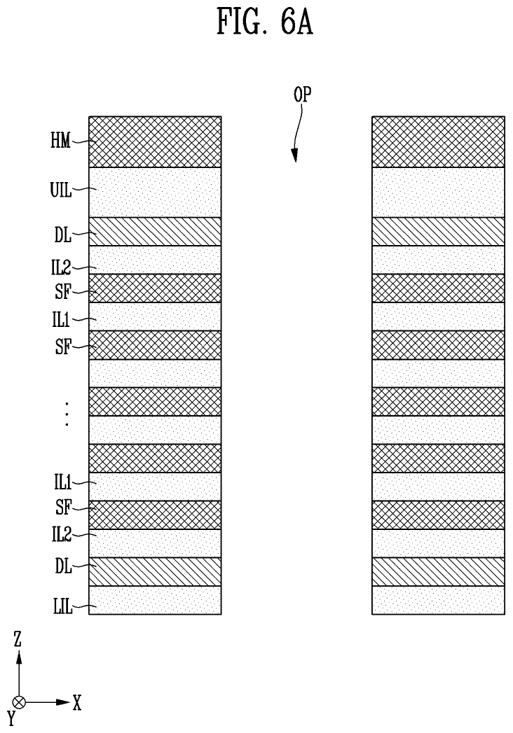

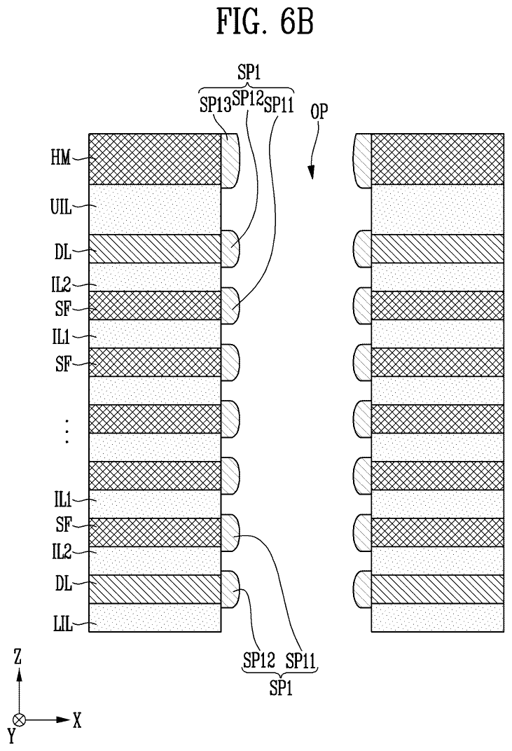

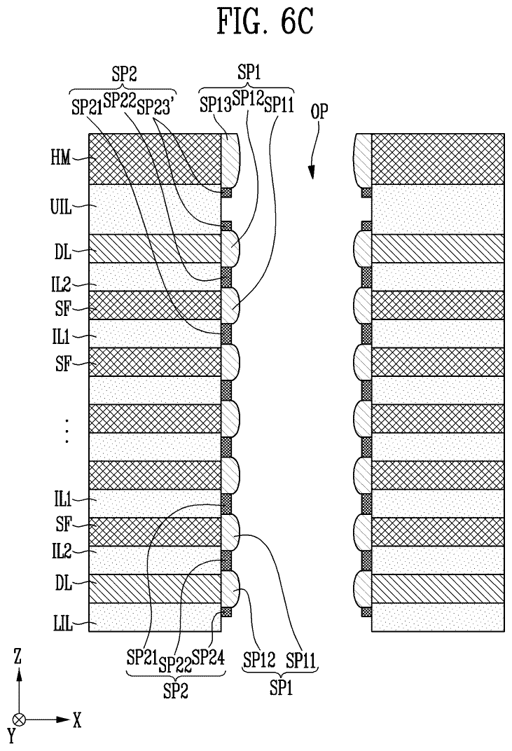

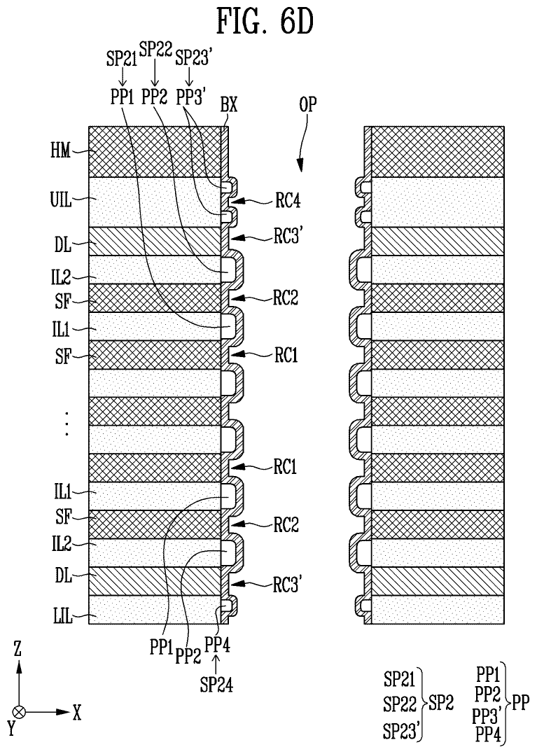

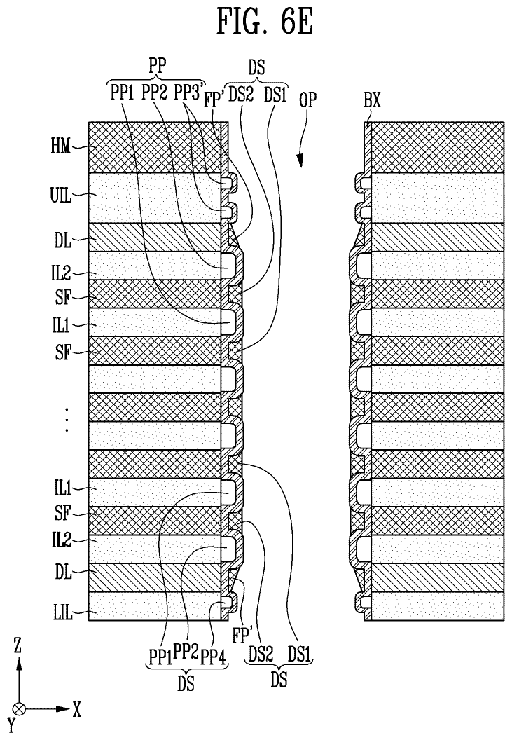

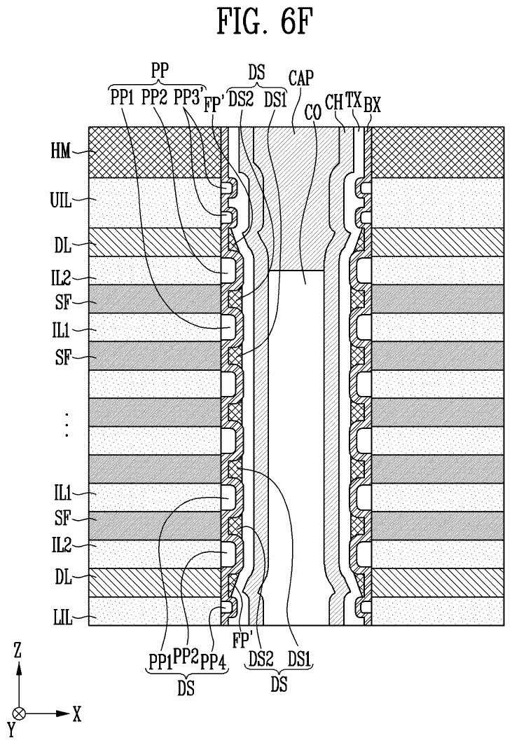

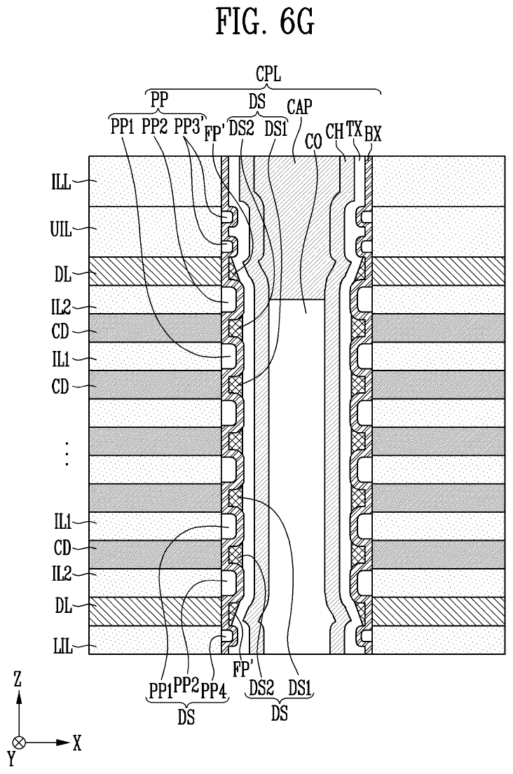

However, the present disclosure is not limited to the embodiments shown in FIGS. 3 and 4A to 4G. For example, as long as the second protruding pattern PP2 has the same size and shape as the first protruding patterns PP1 and the second data storage pattern DS2 has the same size and shape as the first data storage patterns DS1, the size, location, shape, and number of third protruding patterns PP3 may vary. In addition, the size, location, and shape of the filling pattern FP may also vary. An embodiment described with reference to FIGS. 5 and 6A to 6G may be included as one example in the preset disclosure.

FIG. 5 is a cross-sectional view illustrating the structure of a memory device according to an embodiment of the present disclosure.

The configurations which are the same as those described above with reference to FIG. 3 will be described briefly with reference to FIG. 5, or the descriptions thereof may be omitted.

As shown in FIG. 5, the conductive patterns CD and the first interlayer insulating layers IL1 may be alternately stacked in the Z direction, the dummy patterns DP may be spaced apart from the conductive patterns CD in the Z direction, and the second interlayer insulating layer IL2 may be disposed between any one of the conductive patterns CD and any one of the dummy patterns DP in the same manner as described above with reference to FIG. 3. The protruding patterns PP may be located on the side surfaces of the first and second interlayer insulating layers IL1 and IL2. The data storage patterns DS may be located between the protruding patterns PP.

The first protruding patterns PP1 may be disposed on side surfaces of the first interlayer insulating layers IL1 in a horizontal direction. The second protruding patterns PP2 may be disposed on side surfaces of the second interlayer insulating layers IL2 in the horizontal direction. The second protruding patterns PP2 may have the same size and shape as the first protruding patterns PP1. The first data storage patterns DS1 may be located between the first protruding patterns PP1. The second data storage patterns DS2 may be located between any one of the first protruding patterns PP1 and any one of the second protruding patterns PP2. The second data storage patterns DS2 may be located on side portions of the uppermost and lowermost conductive patterns CD. The second data storage patterns DS2 may have the same and shape as the first data storage patterns DS1.

Referring to FIG. 5, contrary to FIG. 3, the protruding patterns PP may include third protruding patterns PP3′ formed on a side surface of the upper insulating layer UIL. The third protruding patterns PP3′ may have smaller lengths in the Z direction and the horizontal direction than the first and second protruding patterns PP1 and PP2. The third protruding patterns PP3′ of FIG. 5 may have smaller lengths in the vertical direction and the horizontal direction than the third protruding pattern PP3 of FIG. 3. In addition, two third protruding patterns PP3′ may be formed on the side surface of the upper insulating layer UIL. The third protruding patterns PP3′ may be spaced apart from each other on the side surface of the upper insulating layer UIL in the Z direction.

In addition, the protruding patterns PP may include fourth protruding patterns PP4 formed on the side surface of the lower insulating layer LIL. The fourth protruding patterns PP4 may have smaller lengths in the Z direction and the horizontal direction than the first and second protruding patterns PP1 and PP2. The size and shape of the fourth protruding patterns PP4 may correspond to that of the third protruding patterns PP3′.

A filling pattern FP′ may be formed between the second protruding pattern PP2 and the third protruding pattern PP3′. In addition, the filling pattern FP′ may be formed between the second protruding pattern PP2 and the fourth protruding pattern PP4. The filling patterns FP′ may be formed on side portions of the dummy patterns DP. The filling patterns FP′ may be surrounded by the dummy patterns DP. The filling patterns FP′ of FIG. 5 may have a different shape from the filling pattern FP of FIG. 3. Because the third protruding patterns PP3′ and the fourth protruding patterns PP4 each have a smaller size than the third protruding patterns PP3, the space for forming the filling pattern FP′ may be narrower than that shown in FIG. 3. Therefore, the filling patterns FP′ may have an inclined side surface in the Z direction. For example, the filling pattern FP′ surrounded by the first dummy pattern DP1 may decrease in thickness toward the third protruding patterns PP3′. For example, the filling pattern FP′ surrounded by the first dummy pattern DP2 may decrease in thickness toward the fourth protruding patterns PP4.

However, the filling pattern FP′ might not be formed between the third protruding patterns PP3′. Because the size of the third protruding patterns PP3′ is less than that of each of the first and second dummy patterns PP1 and PP2, there might not be enough space between the third protruding patterns PP3′ in which the filling pattern FP′ is disposed.

In addition to the embodiment shown in FIG. 5, although the structure of the cell plug CPL is modified at levels corresponding to the dummy patterns DP, the insulating layer ILL, the upper insulating layer UIL, and the lower insulating layer LIL, such various structures of the cell plug CPL may fall within the scope of right of the present disclosure as long as the data storage patterns DS have repetitive patterns. For example, the memory device may include two third protruding patterns PP3′ separated from each other and might not include the fourth protruding pattern PP4. In another example, the memory device may include the fourth protruding pattern PP4 and the third protruding pattern PP3 shown in FIG. 3 instead of the third protruding patterns PP3′ of FIG. 5. Hereinafter, a method of manufacturing the cell plug CPL as shown in FIG. 5 will be described.

FIGS. 6A to 6G are diagrams illustrating a method of manufacturing a memory device according to another embodiment of the present disclosure.

Some of the configurations of FIGS. 6A to 6G which are the same as those shown in FIGS. 4A to 4G will be briefly described, or might not be described. Differences in configuration between FIGS. 4A to 4G and FIGS. 6A to 6G will be mainly described.

Referring to FIG. 6A, the thickness of the upper insulating layer UIL may be greater than that of the upper insulating layer UIL of FIG. 4A. Further, the thickness of the upper insulating layer UIL may be less than that shown in FIG. 4A, or the thickness of the hard mask HM may be greater or less than that in FIG. 4A.

Referring to FIG. 6B, the distance between the (1-2)th sacrificial pattern SP12 and the (1-3)th sacrificial pattern SP13 may be greater than that in FIG. 4B. The distance between the (1-2)th sacrificial pattern SP12 and the (1-3)th sacrificial pattern SP13 may vary depending on the thickness of the upper insulating layer UIL.

Referring to FIG. 6C, (2-3)th sacrificial patterns SP23′ separated from each other may be formed on the side surface of the upper insulating layer UIL. Because the distance between the (1-2)th sacrificial pattern SP12 and the (1-3)th sacrificial pattern SP13 is greater than the distance between the (1-1)th sacrificial pattern SP11 and the (1-3)th sacrificial pattern SP13, a sacrificial material between the (1-2)th sacrificial pattern SP12 and the (1-3)th sacrificial pattern SP13 may be excessively etched. The above sacrificial material may correspond to the sacrificial material described above with reference to FIG. 4C. Therefore, the (2-3)th sacrificial patterns SP23′ may have lengths in the Z direction and in the horizontal direction than the (2-2)th sacrificial patterns SP22. In addition, the (2-3)th sacrificial patterns SP23′ may be separated from each other in regions adjacent to the first sacrificial patterns SP1.

In addition, (2-4)th sacrificial pattern SP24 may be formed on the side surface of the lower insulating layer LIL. When the sacrificial material is removed from the opening OP, the (2-4)th sacrificial pattern SP24 may remain on the side surface of the lower insulating layer LIL.

Referring to FIG. 6D, the second sacrificial patterns SP2 may be oxidized to form the protruding patterns PP. Because the (2-3)th sacrificial patterns SP23′ have a smaller size than the (2-1)th sacrificial patterns SP21 or the (2-2)th sacrificial patterns SP22, the third protruding patterns PP3′ may have a smaller size than the first protruding patterns PP1 and the second protruding patterns PP2. Because the (2-4)th sacrificial patterns SP24 have a smaller size than the (2-1)th sacrificial patterns SP21 or the (2-2)th sacrificial patterns SP22, the fourth protruding patterns PP4 may have a smaller size than the first protruding patterns PP1 and the second protruding patterns PP2.

The blocking insulating layer BX may be formed on side surfaces of the protruding patterns PP and the inner surface of the opening OP. The blocking insulating layer BX may include third recesses RC3′ located between the second protruding pattern PP2 and the third protruding pattern PP3′ and between the second protruding pattern PP2 and the fourth protruding pattern PP4. Because the second protruding pattern PP2 has a smaller horizontal length than the third protruding pattern PP3′ or the fourth protruding pattern PP4, the third recesses RC3′ may have an asymmetrical shape.

In addition, the blocking insulating layer BX may include a fourth recess RC4 which is located between the third protruding patterns PP3′. Because the third protruding patterns PP3′ have a smaller size than the first and second protruding patterns PP1 and PP2, and the distance between the third protruding patterns PP3′ is less than the distance between the first and second protruding patterns PP1 and PP2, the size of the fourth recess RC4 may have a smaller size than the first and second recesses RC1 and RC2.

Referring to FIG. 6E, filling patterns FP′ may fill the third recesses RC3′ of FIG. 6D. Because the third recesses RC3′ has the asymmetrical shape, the filling patterns FP′ may have a shape in which a horizontal thickness of the filling patterns FP′ varies along the Z direction. In addition, the fourth recess RC4 of FIG. 6D might not be filed with the filling pattern FP′. Because the fourth recess RC4 has a small size, the fourth recess RC4 might not be filled with the data storage material as described with reference to FIG. 4E, or the data storage material may be completely etched from the fourth recess RC4.

Although the third protruding patterns PP3′, the fourth protruding pattern PP4, and the filling patterns FP′ as shown in FIG. 6E are formed in a different manner from those shown in FIG. 4E, the data storage patterns DS may be formed in the same manner as shown in FIG. 4E. For example, the first data storage patterns DS1 between the first protruding patterns PP1 and the second data storage patterns DS2 between the first protruding pattern PP1 and the second protruding pattern PP2 may have the same size and shape.

Referring to FIG. 6F, the tunneling layer TX, the channel layer CH, the core pillar CO, and the capping layer CAP may be sequentially formed in the opening OP. The tunneling layer TX may contact the data storage patterns DS, the blocking insulating layer BX, and the filling patterns FP′ in the opening OP. The tunneling layer TX may be conformally formed on the side surfaces of the data storage patterns DS, the blocking insulating layer BX, and the filling patterns FP′. The channel layer CH may be conformally formed on the side surface of the tunneling layer TX. However, the specific shapes of the tunneling layer TX, the channel layer CH, the core pillar CO, and the capping layer CAP are not limited those shown in FIG. 6F.

Referring to FIG. 6G, the sacrificial layers SF may be replaced by the conductive patterns CD, and the hard mask HM may be replaced by the insulating layer ILL.

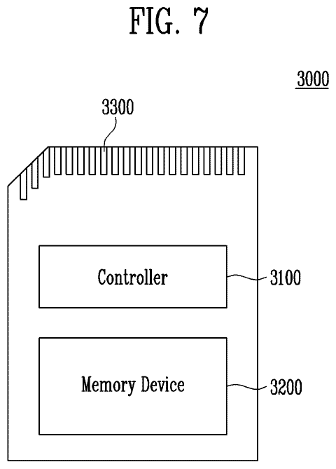

FIG. 7 is a diagram illustrating a memory card system 3000 to which a memory device according to an embodiment of the present disclosure is applied.

Referring to FIG. 7, the memory card system 3000 may include a controller 3100, a memory device 3200, and a connector 3300.

The controller 3100 may be coupled to the memory device 3200. The controller 3100 may be configured to access the memory device 3200. For example, the controller 3100 may control a program operation, a read operation or an erase operation, or a background operation of the memory device 3200. The controller 3100 may be configured to provide an interface between the memory device 3200 and a host. The controller 3100 may be configured to drive firmware for controlling the memory device 3200. For example, the controller 3100 may include components such as a Random Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. For example, the controller 3100 may be configured to communicate with the external device through at least one of various communication protocols such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be defined by at least one of the above-described various communication protocols.

The memory device 3200 may include a plurality of memory cells and may be configured in the same manner as the memory device 100 shown in FIG. 1.

The controller 3100 and the memory device 3200 may be integrated into a single semiconductor device to constitute a memory card. For example, the controller 3100 and the memory device 3200 may constitute a memory card such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro, or eMMC), an SD card (SD, miniSD, microSD, or SDHC), and a Universal Flash Storage (UFS).

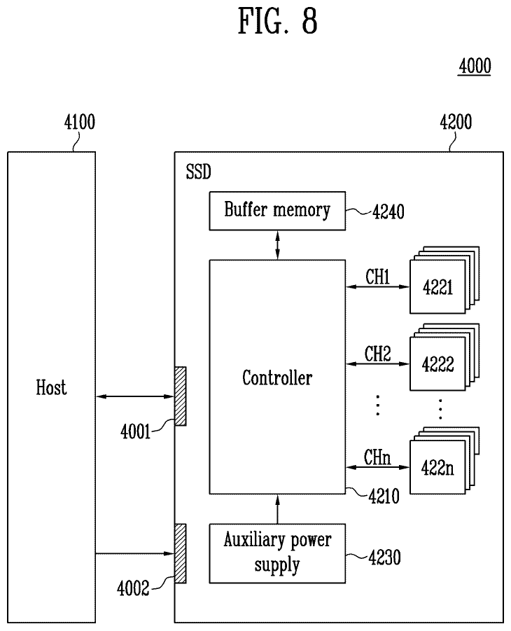

FIG. 8 is a diagram illustrating a solid state drive (SSD) system 4000 to which a memory device according to an embodiment of the present disclosure is applied.

Referring to FIG. 8, the SSD system 4000 may include a host 4100 and an SSD 4200. The SSD 4200 may exchange a signal with the host 4100 through a signal connector 4001, and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. For example, the signals may be based on an interface between the host 4100 and the SSD 4200. For example, the signals may be defined by at least one of interfaces such as Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), an Integrated Drive Electronics (IDE), Firewire, Universal Flash Storage (UFS), WI-FI, Bluetooth, and NVMe interfaces.

The plurality of memory devices 4221 to 422n may include a plurality of memory cells configured to store data. Each of the plurality of memory devices 4221 to 422n may be configured in the same manner as the memory device 100 shown in FIG. 1.

The auxiliary power supply 4230 may be coupled to the host 4100 through a power connector 4002. The auxiliary power supply 4230 may receive power input from the host 4100 and charge the power. When the supply of power from the host 4100 is not smooth, the auxiliary power supply 4230 may provide power of the SSD 4200. For example, the auxiliary power supply 4230 may be located inside or outside the SSD 4200. For example, the auxiliary power supply 4230 may be located on a main board and provide auxiliary power to the SSD 4200.

The buffer memory 4240 may serve as a buffer memory of the SSD 4200. For example, the buffer memory 4240 may temporarily store data received from the host 4100 or data received from the plurality of memory devices 4221 to 422n, or may temporarily store metadata (e.g., mapping tables) of the memory devices 4221 to 422n. The buffer memory 4240 may include volatile memories such as DRAM, SDRAM, DDR SDRAM, and LPDDR SDRAM, or non-volatile memories such as FRAM, ReRAM, STT-MRAM, and PRAM.

According to an embodiment of the present disclosure, data storage patterns separated from each other in a vertical direction may be stably formed by additionally forming dummy patterns on upper and lower parts of a stacked structure.

It will be apparent to those skilled in the art that various modifications can be made to the above-described examples of embodiments without departing from the spirit or scope of the descriptions. Thus, it is intended that the present disclosure cover all such modifications provided they come within the scope of the appended claims and their equivalents.

What is claimed is:

1. A memory device, comprising:
conductive patterns and first interlayer insulating layers stacked alternately with each other;
a dummy pattern separated from the conductive patterns;
a second interlayer insulating layer located between the conductive patterns and the dummy pattern;
protruding patterns protruding from side surfaces of the first interlayer insulating layers and a side surface of the second interlayer insulating layer; and
data storage patterns located between the protruding patterns.

2. The memory device of claim 1, wherein the protruding patterns comprise:
first protruding patterns disposed on the side surfaces of the first interlayer insulating layers; and
a second protruding pattern disposed on the side surface of the second interlayer insulating layer.

3. The memory device of claim 2, wherein a size and shape of the second protruding pattern corresponds to a size and shape of the first protruding patterns.

4. The memory device of claim 2, wherein the data storage patterns comprise:
first data storage patterns located between the first protruding patterns; and
a second data storage pattern located between one of the first protruding patterns and the second protruding pattern.

5. The memory device of claim 4, wherein a size and shape of the second data storage pattern corresponds to a size and shape of the first data storage patterns.

6. The memory device of claim 1, wherein the dummy pattern is disposed over or under the conductive patterns with the second interlayer insulating layer interposed therebetween.

7. The memory device of claim 1, wherein the dummy pattern includes a nitride.

8. The memory device of claim 1, wherein the dummy pattern includes a different insulating material from the first interlayer insulating layers and the second interlayer insulating layer.

9. The memory device of claim 8, wherein the dummy pattern includes silicon carbon nitride (SiCN).

10. The memory device of claim 1, wherein the data storage patterns are separated from each other by the protruding patterns.

11. The memory device of claim 1, wherein each of the data storage patterns is disposed on each of the conductive patterns, respectively.

12. The memory device of claim 1, wherein an opening is formed through the conductive patterns, the first interlayer insulating layers, the dummy pattern, and the second interlayer insulating layer, and
the protruding patterns and the data storage patterns are formed in the opening.

13. The memory device of claim 12, further comprising a blocking insulating layer extending between the protruding patterns and the data storage patterns.

14. The memory device of claim 13, further comprising:
a tunneling layer contacting the data storage patterns and the blocking insulating layer; and
a channel layer contacting an inner surface of the tunneling layer.

15. The memory device of claim 1, further comprising:
an upper insulating layer disposed on the dummy pattern; and
a third protruding pattern protruding from a side surface of the upper insulating layer.

16. The memory device of claim 15, wherein the protruding patterns comprise:
first protruding patterns disposed on the side surfaces of the first interlayer insulating layers; and
a second protruding pattern disposed on the side surface of the second interlayer insulating layer, and
wherein a size and shape of the third protruding pattern corresponds to a size and shape of the first and second protruding patterns, respectively.

17. The memory device of claim 16, further comprising a filling pattern located between the second protruding pattern and the third protruding pattern.

18. The memory device of claim 17, wherein a size and shape of the filling pattern corresponds to a size and shape of at least one of the data storage patterns.

19. The memory device of claim 16, wherein the dummy pattern includes a nitride.

20. The memory device of claim 15, further comprising an insulating layer disposed on the upper insulating layer,
wherein the insulating layer has a greater thickness than each respective thickness of the first interlayer insulating layers, and
wherein the insulating layer has a greater thickness than each respective thickness of the second interlayer insulating layers.

21. The memory device of claim 1, further comprising:
an upper insulating layer disposed on the dummy pattern; and
third protruding patterns protruding from a side surface of the upper insulating layer.

22. The memory device of claim 21, wherein the dummy pattern includes silicon carbon nitride (SiCN).

23. The memory device of claim 21, wherein the protruding patterns comprise:
first protruding patterns disposed on the side surfaces of the first interlayer insulating layers; and
a second protruding pattern disposed on the side surface of the second interlayer insulating layer, and
wherein a size of the third protruding patterns is less than a size of each of the first and second protruding patterns, respectively.

24. The memory device of claim 21, wherein the third protruding patterns are spaced apart from each other.

25. The memory device of claim 1, further comprising:
a lower insulating layer disposed on the dummy pattern;
fourth protruding patterns protruding from a side surface of the lower insulating layer.

26. The memory device of claim 25, wherein the protruding patterns comprise:
first protruding patterns disposed on the side surfaces of the first interlayer insulating layers; and
a second protruding pattern disposed on the side surface of the second interlayer insulating layer, and
wherein a size of the fourth protruding pattern is less than a size of each of the first and second protruding patterns, respectively.
